(19) United States
(12) Patent Application Publication
(10) Pub. No.: US 2021/0336160 A1
(43) Pub. Date: Oct. 28, 2021

(54) OLED DISPLAY DEVICE

(71) Applicant: WUHAN CHINA STAR OPTOELECTRONICS SEMICONDUCTOR DISPLAY TECHNOLOGY CO., LTD., Wuhan, Hubei (CN)

(72) Inventor: Qian JIANG, Wuhan, Hubei (CN)

(21) Appl. No.: 16/478,263

(22) PCT Filed: Mar. 21, 2019
(86) PCT No.: PCT/CN2019/079099

§ 371 Date: Jul. 16, 2019

(30) Foreign Application Priority Data
Feb. 26, 2019 (CN) 201910143440.5

(51) Int. Cl. H01L 51/00; B32B 3/30; B32B 5/18; B32B 27/28; B32B 27/06

(52) U.S. Cl. CPC H01L 51/0097; B32B 3/30; B32B 5/18; B32B 2457/206; B32B 27/065; H01L 2251/5338; B32B 27/281

(57) ABSTRACT

An OLED display device is provided, including: a supporting structure and an OLED display panel disposed on the supporting structure. The OLED display panel includes a first display region, a second display region, and a third display region. The first display region and the second display region are configured to be folded in opposite directions relative to the third display region respectively, thereby enabling the OLED display panel to display different images on a front side, a back side and a lateral side thereof. Furthermore, the images displayed on the front side and the back side of the OLED display panel can be switched freely. The OLED display device only needs one camera to satisfy a requirement of taking photographs.

### FIELD OF INVENTION

The present invention relates to the technical field of display, and, in particular, to an OLED display device.

### BACKGROUND OF INVENTION

With the development of information transmission technologies and electronic products, Organic Light Emitting Diode (OLED) display devices are becoming more and more widely used. When a flexible OLED is applied to a flat display device, the following two methods are mainly implemented: 1. Single-sided display application: the flexible OLED is applied to a plane of a flat display device (or a plane and edges of a mobile device), while the other plane is not provided with a display panel. 2. Single-sided dynamic bending application: the flexible OLED is applied to a dynamic bending plane display device, wherein a main plane of the display device is configured to be folded, thereby realizing a flat display device having an openable/foldable display panel. However, the single-sided dynamic bending application is still in development.

Conventional technologies of a flat display device have drawbacks as follows:

1. Low screen-to-body ratio: a screen-to-body ratio of a portable flat display is about 0.5, and a screen-to-body ratio of a portable flat display can no longer effectively be higher. Both the application of the single-sided display and the application of the dynamic bending have a problem of low screen-to-body ratio.

2. Low utilization of bendability: a flexible OLED display panel being made of polyimide has bendability; however, the bendability is not effectively utilized, wherein the utilization of bendability of the single-sided display OLED display panel is nearly 0%. The dynamic bending OLED display panel is still in development; thus, there is no mature product.

3. A requirement for two cameras: A conventional flat display device must use a front camera and a rear camera to realize a flat display device with a function of taking photos of an object in front of and behind the flat display device.

Therefore, there is a need to provide a new OLED display to solve the above technical problems.

### SUMMARY OF INVENTION

The present invention provides an OLED display device in order to solve technical problems of a conventional OLED display device, such as low screen-to-body ratio, low utilization of bendability, and a requirement for two cameras.

To solve the above technical problems, technical solutions provided by the present invention are described as follows:

An embodiment of the present invention provides an OLED display device, including a supporting structure, a notch defined in a back side of the supporting structure, and an OLED display panel disposed on the supporting structure. The OLED display panel includes a first display region, a second display region, and a third display region, wherein the first display region and the second display region are disposed on opposite sides of the third display region respectively. The first display region and the second display region are configured to be folded in opposite directions relative to the third display region respectively, thereby making the first display region and the second display region in two different planes respectively.

Furthermore, the first display region, the second display region, and the third display region are respectively disposed at a back side, a front side and, a lateral side of the supporting structure.

Furthermore, the first display region or the second display region is provided with a notch.

Furthermore, the notch is U-shaped, tear-shaped or round-hole shaped.

Furthermore, a flexible circuit board is disposed on a side of the first display region away from the third display region and/or on a side of the second display region away from the third display region. The flexible circuit board is bent relative to a lateral edge of the supporting structure to a back side of the supporting structure.

Furthermore, a bending radius of the flexible circuit board is decided by a thickness of the OLED display device.

Furthermore, the flexible circuit board is provided with an integrated circuit.

Furthermore, the flexible circuit board is provided with a buffer layer.

Furthermore, material of the buffer layer is foam.

Furthermore, the lateral edge of the supporting structure is a circular arc.

The present embodiment provides an OLED display device, including a supporting structure and an OLED display panel disposed on the supporting structure. The OLED display panel includes a first display region, a second display region, and a third display region. The first display region and the second display region are disposed on opposite sides of the third display region respectively. The first display region and the second display region are configured to be folded in opposite directions relative to the third display region respectively, thereby making the first display region and the second display region in two different planes respectively.

Furthermore, the first display region, the second display region, and the third display region are respectively disposed at a back side, a front side, and a lateral side of the supporting structure.

Furthermore, the first display region and the second display region have the same shape.

Furthermore, the first display region or the second display region is provided with a notch.

Furthermore, the notch is U-shaped, tear-shaped or round-hole shaped.

Furthermore, the OLED display panel includes a substrate, and material of the substrate is polyimide.

Furthermore, a flexible circuit board is disposed on a side of the first display region away from the third display region and/or on a side of the second display region away from the third display region. The flexible circuit board is bent along a lateral edge of the supporting structure to a back side of the supporting structure.

Furthermore, a bending region radius of the flexible circuit board is decided by a thickness of the OLED display device.

Furthermore, the flexible circuit board is provided with an integrated circuit chip.

Furthermore, the lateral edge of the supporting structure is a circular arc.

Advantageous effects of the present invention: The present invention provides an OLED display device. A first region of the OLED display device and a second region of the OLED display device are configured to be folded in opposite directions relative to a third display region of the OLED display device respectively, thereby making the first display region, the second display region and the third display region able to display at the same time, further making the OLED display device have a high screen-to-body ratio. A back side, a front side and a lateral side of the OLED display device can display different images. The images displayed on the back side and front side of the OLED display device can be switched freely. The OLED display device only needs one camera to satisfy a requirement of taking photographs, thereby avoiding a situation of disposing two cameras on an OLED display device.

### DESCRIPTION OF DRAWINGS

In order to more clearly illustrate the technical solutions in embodiments of the present invention, drawings used in the description of embodiments will be briefly described below. Apparently, the drawings in the following description are only some embodiments of the present invention, those skilled in the art can derive other drawings according to these drawings without paying creative efforts.

FIG. 1a is a schematic structural diagram showing a first OLED display panel with a U-shaped notch before being folded according to an embodiment of the present invention.

FIG. 1b is a schematic structural view showing a first OLED display panel with a tear-shaped notch before being folded according to an embodiment of the present invention.

FIG. 1c is a schematic structural view showing a first OLED display panel with a round-hole shaped notch before being folded according to an embodiment of the present invention.

FIG. 2 is a schematic structural view showing a first OLED display device with a U-shaped notch after being folded according to an embodiment of the present invention.

FIG. 3 is a schematic structural view showing a first OLED display device according to an embodiment of the present invention.

FIG. 4 is a schematic structural view showing a second OLED display device with a U-shaped notch before being folded according to an embodiment of the present invention.

### DETAILED DESCRIPTION OF PREFERRED EMBODIMENTS

The following description of the various embodiments is provided to illustrate the specific embodiments. Directional terms mentioned in the present invention, such as [upper], [lower], [front], [rear], [left], [right], [inside], [outside], [next to], etc., are only the reference of drawings. Therefore, the directional terms used are for the purpose of illustration and understanding, instead of limiting the present invention. In the drawings, the structurally similar components are denoted by the same reference numerals.

The present embodiment can solve technical problems of a conventional OLED display device, such as low screen-to-body ratio, low utilization of bendability, and a requirement for two cameras.

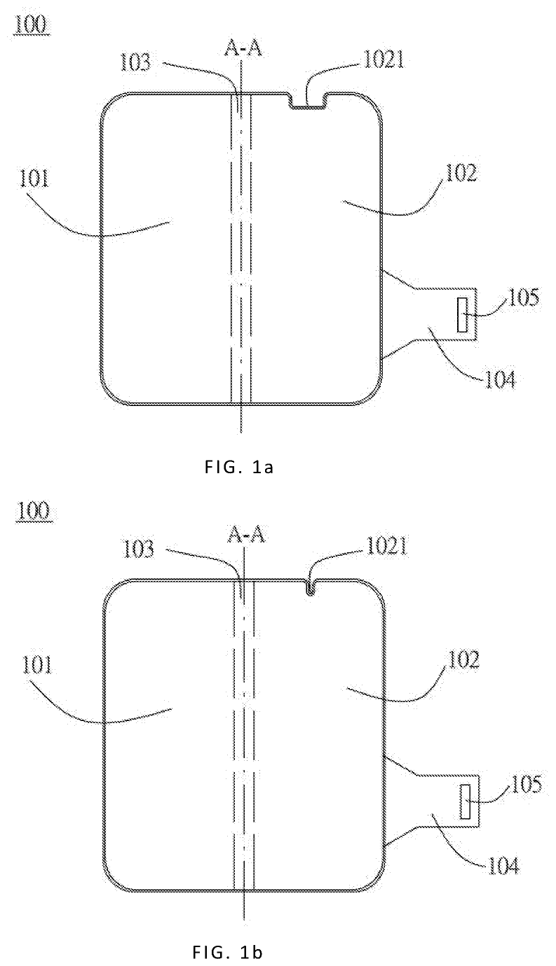

As shown in FIG. 1a, the present embodiment provides an OLED display panel 100. The OLED display panel 100 includes a first display region 101, a second display region 102 and a third display region 103, wherein the first display region 101 and the second display region 102 are disposed on opposite sides of the third display region 103 respectively. The third display region 103 is foldable. The first display region 101 and the second display region 102 are configured to be folded in opposite directions relative to a centerline position A-A of the third display region 103 respectively. A planar shape of the first display region 101 and a planar shape of the second display region 102 are both rectangular. However, the planar shape of the first display region 101 and the planar shape of the second display region 102 should not be limited to the rectangular shape in the present embodiment, but should be the shape conforming the shapes of the front and back sides of the OLED display device 10 to which the first display region 101 and the second display region 102 are applied, respectively.

A substrate of the OLED display panel 100 is made of polyimide, thereby making the OLED display panel 100 have higher bendability. Of course, the OLED display 100 can also be made of other flexible materials like plastics, and the present embodiment should not be limited thereto.

A notch 1021 is defined in a top middle position of the second display region 102; that is, the notch 1021 is defined in the front side of the OLED display panel 100. The notch 1021 is U-shaped. However, a position where the notch 1021 is defined is not limited to the position of the notch 1021 shown in FIG. 1, but can also be defined in any position of the second display region 102. A position of the notch 1021 and a size of the notch 1021 can be adjusted according to specific needs. In order not to affect user's viewing experience on the OLED display panel 100, the notch 1021 is generally defined in the upper right corner, the upper left corner, or the top middle position of the second display region 102. Moreover, the notch 1021 can also be defined in the first display region 101; that is, the notch 1021 is defined in the back side of the OLED display panel 100, and details thereof will not be described here.

As shown in FIG. 1b and FIG. 1c, the notch 1021 is not limited to be U-shaped but can be tear-shaped, round-hole shaped or other shapes. On the other hand, the OLED display panel 100 can omit the notch 1021; that is, there is no notch in each surface of the OLED display panel 100. In the present embodiment, the OLED display panel 100 with a U-shaped notch 1021 is taken as an example for illustration.

The OLED display panel 100 is a flexible OLED display panel with a complete structure, including a substrate, an OLED light emitting layer, an encapsulation layer, and a flexible touch screen.

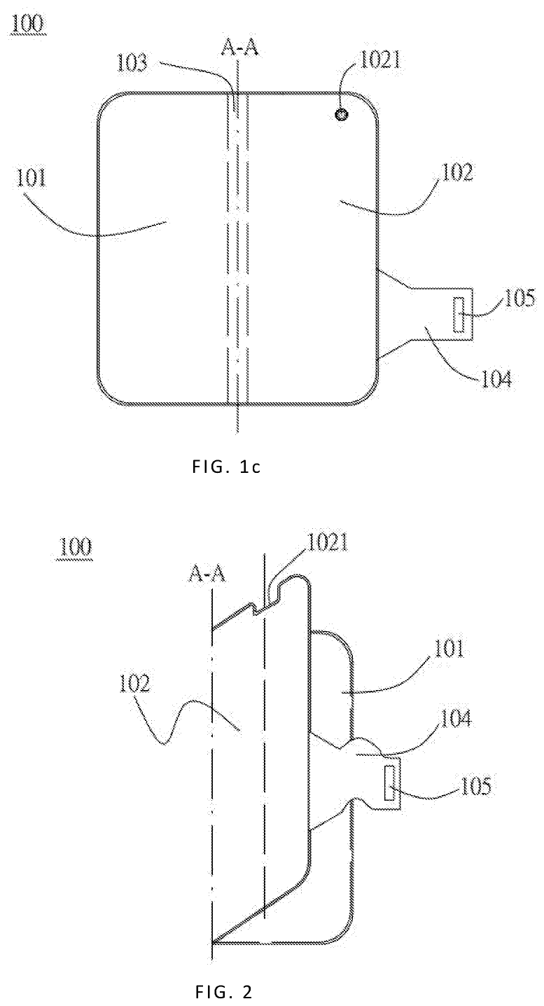

As shown in FIG. 2, the first display region 101 and the second display region 102 are in two different planes respectively, after being folded in opposite directions relative to a centerline A-A of the third display region 103 respectively. The second display region 102 is at a back side of the OLED display panel 100, the first display region 101 is at a front side of the OLED display panel 100 and the third display region 103 is at a lateral side of the OLED display panel 100.

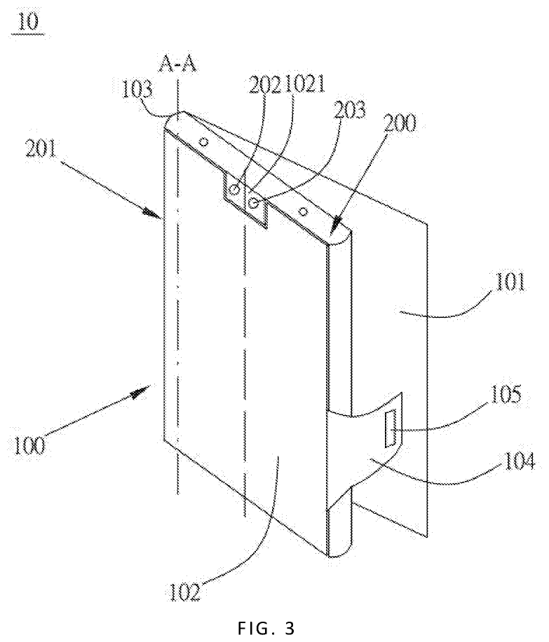

As shown in FIG. 3, the present embodiment provides an OLED display device 10. The OLED display device 10 includes a supporting structure 200 and the OLED display panel 100 disposed on the supporting structure 200. The OLED display panel 100 includes the first display region 101, the second display region 102 and the third display region 103, wherein the first display region 101 and the second display region 102 are disposed on opposite sides of the third display region 103 respectively. The third display region 103 is bendable, thereby making the first display region 101 and the second display region 102 can be folded in opposite directions relative to the centerline A-A of the third display region 103. After the first display region 101 and the second display region 102 are folded in opposite directions relative to the centerline A-A of the third display region 103, the second display region 102 is attached to a front side of the supporting structure 200, the first display region 101 is attached to a back side of the supporting structure 200, and the third display region 103 is attached to one of lateral edges 201 of the supporting structure 200.

Because the lateral side 201 of the supporting structure 200 of the OLED display device 10 according to the present embodiment is a circular arc, the third display region 103 is also a circular arc after the OLED display panel 100 is folded. However, the present embodiment should not be limited thereto. For example, the lateral edge 201 of the supporting structure 20 can also have other smooth shapes.

In the present embodiment, a flexible circuit board 104 is disposed on a side of the second display region 102 away from the third display region 103, and the flexible circuit board 104 is electrically connected to the second display region 102. As shown in FIG. 3, the second display region 102 is fixed on a front side of the supporting structure 200, and the flexible circuit board is fixed on one of long edges of the supporting structure 200. The flexible circuit board 104 is folded relative to the long edge of the supporting structure 200 from the front side of the supporting structure 200 to a back side of the supporting structure 200, and the flexible circuit board 104 is then attached to the back side of the supporting structure 200. At the same time, the first display region 101 is attached to the back side of the supporting 200 and covers the flexible circuit board 104. A bending radius of the flexible circuit board 104 is decided by a thickness of the OLED display device 10. Specifically, when the thickness of the OLED display device 10 is large, the bending radius of the flexible circuit board 104 is large; when the thickness of the OLED display device 10 is small, the bending radius of the flexible circuit board 104 is small. At the same time, a thickness of a portion of the flexible circuit board 104 can be thinned to reduce stresses of metal wirings on a surface of the flexible circuit board 104 after the flexible circuit board 104 is bent, thereby reducing a risk of breakage of the metal wirings on the surface of the flexible circuit board 104, and improving a lifetime of the OLED display device.

The flexible circuit board 104 can also be disposed on a side of the first display region 101 away from the third display region 103, and the flexible circuit board 104 is electrically connected to the first display region 101. The flexible circuit board 104 is fixed on one of long edges of the supporting structure 200. The flexible circuit board 104 is folded relative to the long edge of the supporting structure 200 from a back side of the supporting structure 200 to a front side of the supporting structure 200, and the flexible circuit board 104 is then attached to the front side of the supporting structure 200. At the same time, the first display region 101 is attached to the front side of the supporting 200 and covers the flexible circuit board 104.

Furthermore, two flexible circuit boards 104 can be disposed on a side of the first display region 101 away from the third display region 103 and on a side of the second display region 102 away from the third display region 103 respectively. The two flexible circuit boards 104 are electrically connected to the first display region 101 and the second display region 102 respectively.

Furthermore, an integrated circuit (IC) 105 is disposed on the flexible circuit board 104 to realize an electrical connection of the OLED display panel 100 and the supporting structure 200, thereby enabling the OLED display 100 to display an image. The first display region 101, the second display region 102, and the third display region 103 are able to display an image, thereby making a screen-to-body ratio of the OLED display device 10 be nearly 100%, and better realizing a function of full-screen display of the OLED display panel 100. The first display region 101 and the second display region 102 are main display regions for displaying a main image; the third display region 103 is a secondary display region for displaying a small graphic, such as a usage state of the OLED display device 10 (charging, standby, signal strength of a communication network, etc.). The first display region 101 and the second display region 102 can display same or different images. For example, different image signals are transmitted to the first display region 101 and the second display region 102 respectively when the two display regions display different images; same image signals are transmitted to the first display region 101 and the second display region 102 respectively when the two display regions display same images. Therefore, images displayed by the first display region and the second display region can be switched freely. In other words, an image can be switched from the first display region 101 to the second display region 102 and can be switched from the second display region 102 to the first display region 101, thereby realizing a function that an image of the OLED display device 10 can be switched between a front side and a back side thereof. Because the first display region 101 and the second display region 102 share the flexible circuit board 104, the first display region 101 and the second display region 102 have the same display area and the same resolution ratio. Therefore, the same level of image quality can be achieved.

Furthermore, to ensure a surface flatness of the supporting structure 200, a notch with a certain depth (not shown) is configured to be defined in a back side of the supporting structure 200, and the flexible circuit board 104 is fixed in the notch. In addition, a buffer layer (not shown) can be formed on the flexible circuit board 104, wherein material of the buffer layer can be formed by foam.

A notch 1021 is defined in a back side of the OLED 100, wherein a camera 202 and a voice device 203 are disposed in the notch 1021. The camera 202 and the voice device 203 can be exposed after the third display region 103 is bent, thereby realizing a function of photography and playing voice. In other words, a photography requirement can be satisfied by only arranging one camera on the OLED display device 10. Users can take a photo by directing the notch 1021 toward to an object to be photographed. There is no need to arrange two cameras on an OLED display device, thereby raising a body-to-screen ratio, and reducing a cost.

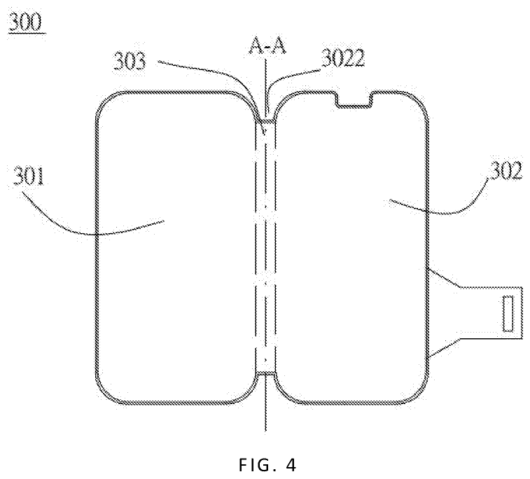

FIG. 4 provides a schematic structural view showing a second OLED display device 300 with a U-shaped notch before being folded according to an embodiment of the present invention. As shown in FIG. 4, two notches 3022 are respectively defined in a top and a bottom of a third display region 303 between a first display region 301 and a second display region 302. The notch 3021 is U-shaped. Each of four corners of the first display region 301 and each of four corners of the second display region 302 are circular. A bending method and a fixing method applied to the OLED display panel 300 are same as the bending method and the fixing method applied to the OLED display panel 100, and will not be described in detail herein.

The OLED display device 10 can be any product or component having a display function, such as an OLED panel, a mobile phone, a tablet computer, a television, a display device, a laptop, a digital photo frame, a navigator.

Advantageous effects of the present invention are as follows. The present invention provides an OLED display device. A first region of the OLED display device and a second region of the OLED display device are configured to be folded in opposite directions relative to a third display region of the OLED display device respectively, thereby making the first display region, the second display region and the third display region able to display image at the same time. Thus, the OLED display device has a high screen-to-body ratio. A back side, a front side and a lateral side of the OLED display device can display different images. The images displayed on the back side and front side of the OLED display device can be switched freely. The OLED display device only needs one camera to satisfy a requirement of taking photographs, thereby avoiding a situation of disposing two cameras on an OLED display device.

In summary, although the present invention has been disclosed above in the preferred embodiments, the above preferred embodiments are not intended to limit the invention. Those skilled in the art can make various modifications and refinements without departing from the scope of the present invention, and the scope of protection of the present invention is defined by the scope defined by the claims.

What is claimed is:

1. An Organic Light Emitting Diode (OLED) device, comprising:
a supporting structure;
a notch defined in a back side of the supporting structure; and
an OLED display panel disposed on the supporting structure, wherein the OLED display panel comprises:
a first display region;
a second display region; and
a third display region;
wherein the first region and the second display region are disposed on opposite sides of the third display region respectively, the first display region and the second display region are configured to be folded in opposite directions relative to the third display region respectively, thereby making the first display region and the second display region in two different planes respectively.

2. The OLED device as claimed in claim 1, wherein the first display region, the second display region and the third display region are respectively disposed at a back side, a front side and a lateral of the supporting structure.

3. The OLED device as claimed in claim 1, wherein the first display region or the second display region is provided with a notch.

4. The OLED device as claimed in claim 3, wherein the notch is U-shaped, tear-shaped or round-hole shaped.

5. The OLED device as claimed in claim 1, wherein a flexible circuit board is disposed on a side of the first display region away from the third display region and/or on a side of the second display region away from the third display region, the flexible circuit board is bent relative to a lateral edge of the supporting structure to a back side of the supporting structure.

6. The OLED device as claimed in claim 5, wherein the bending radius of the flexible circuit board is decided by a thickness of the OLED display device.

7. The OLED device as claimed in claim 5, wherein the flexible circuit board is provided with an integrated circuit.

8. The OLED device as claimed in claim 5, wherein the flexible circuit board is provided with a buffer layer.

9. The OLED device as claimed in claim 8, wherein material of the buffer layer is foam.

10. The OLED device as claimed in claim 5,
wherein the lateral edge of the supporting structure is a circular arc.

11. An Organic Light Emitting Diode (OLED) device, comprising:
a supporting structure; and
an OLED display panel disposed on the supporting structure, wherein the OLED display panel comprises:
a first display region;
a second display region; and
a third display region;
wherein the first region and the second display region are disposed on opposite sides of the third display region respectively, the first display region and the second display region are configured to be folded in an opposite direction relative to the third display region respectively, thereby making the first display region and the second display region in two different planes respectively.

12. The OLED device as claimed in claim 11, wherein the first display region, the second display region and the third display region are respectively disposed at a back side, a front side and a side of the supporting structure.

13. The OLED device as claimed in claim 12, wherein the first display region and the second display region have the same shape.

14. The OLED device as claimed in claim 11, wherein the first display region or the second display region is provided with a notch.

15. The OLED device as claimed in claim 14, wherein the notch is U-shaped, tear-shaped or round-hole shaped.

16. The OLED device as claimed in claim 11, wherein the OLED display panel comprises a substrate, and material of the substrate is polyimide.

17. The OLED device as claimed in claim 11, wherein a flexible circuit board is disposed on a side of the first display region away from the third display region and/or on a side of the second display region away from the third display region, the flexible circuit board is bent relative to a lateral edge of the supporting structure to a back side of the supporting structure.

18. The OLED device as claimed in claim 17, wherein the bending radius of the flexible circuit board is decided by a thickness of the OLED display device.

19. The OLED device as claimed in claim 17, wherein the flexible circuit board is provided with an integrated circuit.

20. The OLED device as claimed in 17, wherein the lateral edge of the supporting structure is a circular arc.
